(19) United States
(12) Patent Application Publication
(10) Pub. No.: US 2004/0087163 A1
(43) Pub. Date: May 6, 2004

(54) Method for forming magnetic clad bit line

(76) Inventors: Robert Steimle, Austin, TX (US); Valli Arunachalam, Austin, TX (US); Mark V. Raymond, Austin, TX (US); Peter L. G. Ventzek, Austin, TX (US); Carole Barron, Austin, TX (US)

Correspondence Address: MOTOROLA INC, AUSTIN INTELLECTUAL PROPERTY, LAW SECTION, 7700 WEST PARMER LANE MD: TX32/PL02, AUSTIN, TX, 78729

(21) Appl. No.: 10/283,601

(22) Filed: Oct. 30, 2002

(51) Int. Cl. H01L 21/311

(52) U.S. Cl. 438/694

(57) ABSTRACT

A magnetic clad bit line structure (274) for a magnetic memory element and its method of formation are disclosed. The magnetic clad bit line structure (274) extends within a trench (258) and includes a conductive material (250), magnetic cladding sidewalls (262) and a magnetic cladding capping layer (272). The magnetic cladding sidewalls (262) are formed by sputtering a material within the trench (258) and selectively resputtering the material deposited at the bottom of the trench (258) onto the adjacent sidewalls of the trench (258).

### FIELD OF THE INVENTION

The present invention relates generally to a magnetic random access memory (MRAM) device and a fabricating method thereof, and more particularly to a method for forming a MRAM device bit line structure.

### BACKGROUND OF THE INVENTION

Magnetic random access memory (MRAM) technology is currently one type of non-volatile memory technology being developed and evaluated by the semiconductor industry. MRAM technology may also prove useful as dynamic random access memory (DRAM) or static random access memory (SRAM) replacements. There are two main types of MRAM: MTJ (magnetic tunnel junction) and GMR (giant magnetoresistive) MRAM. FIG. 1 shows a portion, or a memory bit, of an MTJ array 10 which includes a write line or a bit line 12 intersected by a number of digit lines, one of which is illustrated in FIG. 1 as digit line 14. At each intersecting bit line and digit line, a magnetic tunnel junction sandwich 16 forms a memory element in which one “bit” of information is stored. The magnetic tunnel junction sandwich 16 is comprised of a non-magnetic material 18 between a magnetic layer of fixed magnetization vector and a magnetic layer in which the magnetization vector can be switched; these will be referred to as a fixed layer 20 and a free or switching layer 22.

It is advantageous for a variety of reasons to increase the packing density of memory cells in a memory array. A number of factors influence packing density; they include memory element size and the relative dimensions of associated memory cell circuitry, i.e. bit lines and digit lines, and any semiconductor switching or access device within the memory cell.

For example, referring to FIG. 2, a cross-sectional view of a portion of a prior art MRAM bit line structure 100 is shown. (The bit line structure 100 can be a bit line structure in an MTJ array or a word line structure in a GMR array.) The bit line structure 100 includes a conductive material 104 surrounded by magnetic cladding members 103 and 106. The magnetic cladding members 103 are formed using high-permeability materials that have magnet domains in the plane of the cross-section shown in FIG. 2 which are magnetized and demagnetized upon the application and removal of an applied magnetic field. When current is applied through the conductive material 104, the corresponding magnetic fields associated with the magnetic cladding members 103 and 106 help to enhance the magnitude and more effectively focus the overall magnetic field associated with the bit line structure 100 toward its associated memory element (not shown). Additionally, the magnetic cladding members 103 and 106 also help to shield the bit line's magnetic field from memory cells associated with other adjacent bit lines, thereby protecting their programming state information.

The prior art method for forming the bit line structure 100 includes first etching a trench 102 in a dielectric layer 101. Next, a diffusion barrier 105, e.g. a layer of tantalumn, is deposited over the dielectric layer 101 and in the trench 102, followed by deposition of a high-permeability magnetic material, such as a layer of an alloy of nickel-iron (NiFe) or nickel-iron-cobalt (NiFeCo). The layer of high-permeability magnetic material is then anisotropically etched to form magnetic cladding sidewall (spacer) members 103 adjacent the trench sidewalls. After forming the magnetic cladding sidewall members 103, a conductive material 104, such as copper or aluminum, is deposited overlying the dielectric layer 101 and within the trench opening 102. Then, portions of the conductive material 104 not contained within the opening 102 are removed using a chemical mechanical polishing (CMP) process. Finally, a patterned, overlying layer of high-permeability magnetic material forms the magnetic cladding capping member 106.

There are several problems associated with this known process for forming cladding members 103. One problem occurs because typically a dry, sputter etch is used to anisotropically etch the high-permeability magnetic material. Many sputter etch systems in use today have an inductively coupled etched chamber with a dome formed of a dielectric material, such as alumina. During etch of the high-permeability magnetic material, atoms of the magnetic material will deposit on the dome, which adversely affects the etching capability of the system. To rectify this problem, the dome must be cleaned or conditioned after etching each wafer which imposes an undesirable increase in manufacturing time and decreases in wafer throughput. Furthermore, the dome cleaning process involves etching a silicon dioxide layer on a wafer in a chlorine environment, and residual amounts of chlorine in the etch chamber will corrode the high-permeability magnetic material used to clad the sidewalls of the bit line structure 100.

Another problem associated with the above-described process is that following the anisotropic etch of the high-permeability magnetic material, the wafer is removed from the etch chamber and exposed to ambient air before the wafer is placed in a deposition system to deposit conductive material 104. As a result, the exposed portion of the diffusion barrier 105 at the bottom of trench 102 may oxidize. In the case of a tantalum diffusion barrier, a tantalum oxide will form. Tantalum oxide is highly resistive, and therefore the resistivity of the connection between the conductive material 104 (which would be part of bit line 12) and an underlying conductive member (e.g. the sandwiching layer 22) is undesirably high. A high via resistance between the bit line and the magnetic tunnel junction sandwich adversely affects operation of the device. To avoid a high resistance via, any oxidation layer at the bottom of the trench needs to be removed. This is conventionally done in conjunction with the metal deposition process used to form the conductive material 104. The conductive material 104 is deposited in a physical vapor deposition system. Prior to deposition, a pre-clean step is performed which removes any oxidation layer formed on diffusion barrier 105. But this pre-clean step has many of the same problems associated with the anistropic etching of the high-permeability magnetic material described above. Because the pre-clean is effectively a sputter etch process, the diffusion barrier (which is typically a metal, such as tantalum) will sputter onto the dome. A dome clean or conditioning step is periodically performed to maintain the process capability of the chamber, but again this occurs to the detriment of wafer throughput.

Therefore a need exists for a method for forming magnetic cladding on the sidewalls of a bit line which improves the cycle time of processing wafers, which does not result in oxidation of the underlying diffusion barrier, and which does not impose time-consuming equipment cleaning steps. Furthermore, it would be advantageous for such a method to be scalable as widths of bit lines shrink with advances in other wafer fabrication technology.

### BRIEF DESCRIPTION OF THE FIGURES

The present invention is illustrated by way of example and not limitation in the accompanying figures, in which like references indicate similar elements, and in which:

FIG. 1 includes a cross-sectional diagram illustrating a portion of a prior art MTJ MRAM cell;

FIG. 2 includes a cross-sectional diagram illustrating a prior art MRAM bit line structure;

FIGS. 3-6 include illustrations of cross-sectional views showing the fabrication of a portion of an MRAM array;

FIGS. 7-12 include cross-sectional illustrations of an embodiment of the present invention showing formation of a bit line structure used by memory cells in the MRAM array shown in FIG. 6;

FIG. 13 is a cross-sectional representation of a chamber of a sputtering system which can be used to form magnetic cladding sidewalls in accordance with an embodiment of the present invention; and

FIG. 14 is a representation of how atoms deposit and re-sputter onto sidewalls of a trench to form magnetic cladding sidewalls in accordance with the present invention.

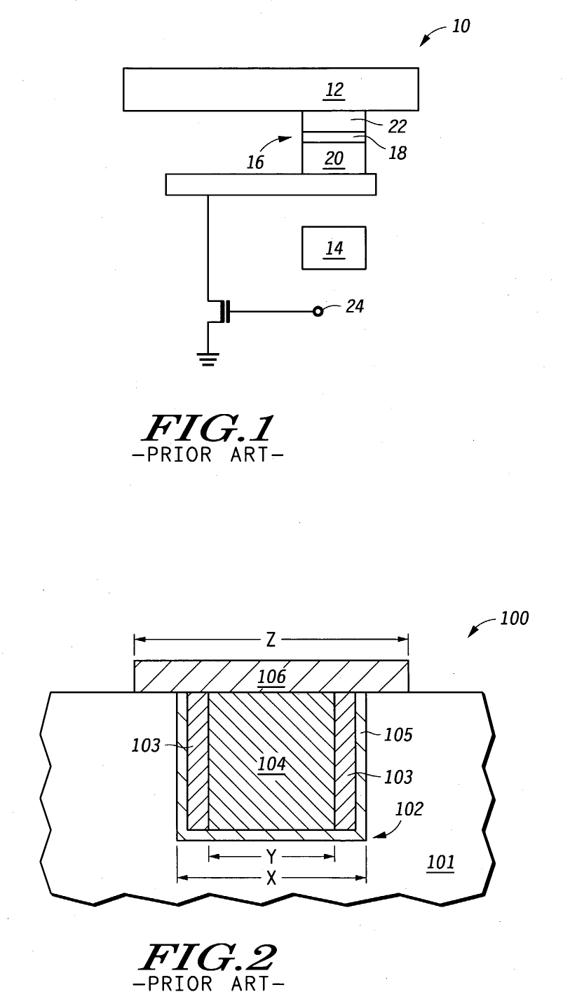

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

An embodiment of the present invention will now be discussed in further detail with respect to the accompanying figures.

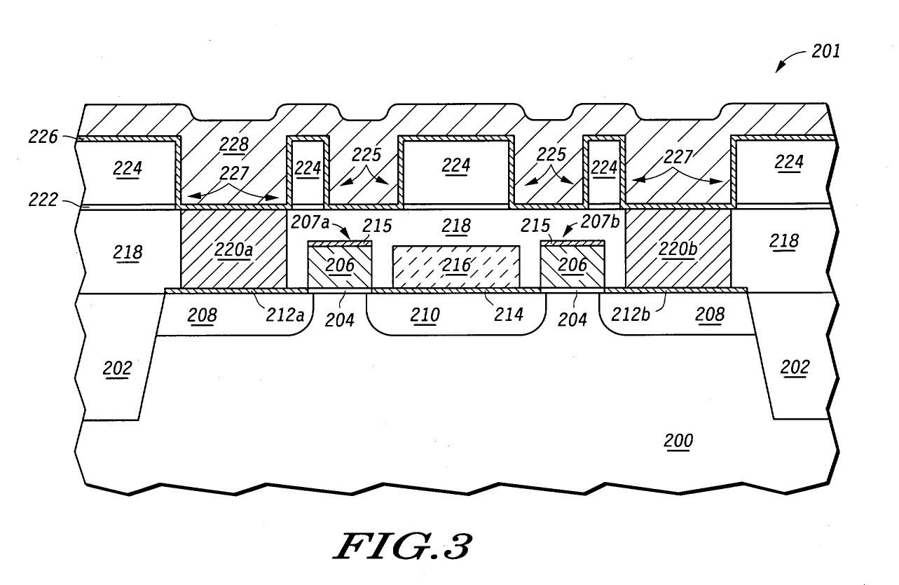

In accordance with an embodiment of the present invention, a magnetic random access memory (MRAM) and its method of formation are disclosed. FIGS. 3-12 illustrate cross-sectional views of fabricating an MRAM device that includes magnetic memory elements, transistors for switching the electrical connections to the magnetic memory elements in reading operations, and associated magnetic memory element digit line and bit line circuitry.

Referring to FIG. 3, a cross-sectional view that includes a partially fabricated MRAM device 201 is illustrated. The MRAM device 201 includes a mono-crystalline substrate 200 (or other suitable substrate, such as silicon on insulator (SOI) or the like), isolation regions 202, and switching transistors 207a and 207b. In accordance with one non-limiting embodiment, the monocrystalline substrate 200 is a P-type silicon substrate and the switching transistors 207a and 207b are NMOS transistors. Switching transistors 207a and 207b further comprise N-type doped regions 208 and 210, gate dielectric layers 204, and gate electrode layers 206. The gate electrode layers 206 also form the word lines that run parallel to the digit line in this embodiment (not shown in FIG. 3). NMOS switching transistors 207a and 207b are fabricated using conventional CMOS processes. Other circuit elements, for example, input/output circuitry, data/address decoders, and comparators, may be contained in the MRAM device, however they are omitted from the drawings for simplicity.

In one embodiment, after forming the switching transistors 207a and 207b, the surface of the N-type doped regions 208 and 210 and the surface of the switching transistors 207a and 207b are silicided to form the regions 212a, 212b, 214 and 215. In a read operation of a memory cell, a positive voltage is be applied to the drain region 210 of the switching transistors 207a and 207b. This is accomplished by having a sense line in contact with the drain regions of all transistor pairs along a particular row of the array. This sense line is parallel to the word and digit line in the present embodiment.

In one embodiment the sense line can be formed by connecting adjacent drain regions 210 and associated silicide regions 214. Alternatively, these drain regions can be connected by a separate conductor. In the embodiment shown in FIG. 3, the sense line is the conductive member 216 which is formed overlying silicided region 214. In accordance with one embodiment, the conductive member 216 is a layer of tungsten that has been formed using a conventional process. Conductive member 216 provides a sense current to subsequently formed magnetic memory elements through transistors 207a and 207b. An explanation regarding the formation of magnetic memory elements will be explained hereinafter. In yet another embodiment, the sense line can be formed from a series of contact windows and contact plugs to the individual drain regions 210 and formation of a separate conductor line.

An interlevel dielectric (ILD) layer 218 is then formed overlying the substrate surface. It is noted that when used in this context “substrate surface” includes the semiconductor device substrate as well as all layers fabricated on the semiconductor device substrate up to the point of processing under discussion. Therefore, substrate surface refers to the present uppermost surface of the substrate, including all structures formed thereon. In one embodiment the ILD layer 218 is a silicon dioxide containing material deposited by chemical vapor deposition (CVD) using tetraethoxysilane (TEOS) as a gas source. Alternatively, ILD layer 218 may be a layer of silicon nitride, a layer of phosphosilicate glass (PSG), a layer of borophosphosilicate glass (BPSG), a spin on glass (SOG) layer, a layer of silicon oxynitride (SiON), a polyimide layer, a layer of a low-k dielectric material, or the like. For the purposes of this specification a low-k dielectric material or low dielectric constant material is any material having a dielectric constant less than approximately 3.6. Deposition can occur alternatively by physical vapor deposition (PVD), a combination of PVD and CVD, or the like.

Conductive plugs 220a and 220b, which provide conduction of sense currents to the subsequently formed magnetic memory elements, are then formed within the ILD layer 218 and interconnect to the silicided regions 212a and 212b. In accordance with one embodiment, most circuit elements of the MRAM device, with the exception of the magnetic memory elements, digit lines, and bit lines are integrated onto the substrate 200 before forming the conductive plugs 220a and 220b. In one embodiment the conductive plugs 220a and 220b comprise an adhesion/barrier layer (not shown) and a plug fill material. The adhesion/barrier layer is typically a refractory metal (such as tungsten (W), titanium (Ti), tantalum (Ta)), a refractory metal nitride, or a combination of refractory metals or their nitrides. The plug fill material is typically tungsten, aluminum, copper, or a like conductive material. The adhesion/barrier layer and plug fill material can be deposited using PVD, CVD, electroplating processes, combinations thereof, or the like. After depositing the adhesion/barrier layer and the plug fill material, the substrate surface is polished to remove portions of the adhesion/barrier layer and plug fill material not contained within the opening to form the conductive plugs 220a and 220b shown in FIG. 3.

After forming the conductive plugs 220a and 220b, digit lines for the subsequently formed magnetic memory elements are defined. As shown in FIG. 3, one method of forming the digit lines is to first form an etch stop layer 222 and an ILD layer 224 over the substrate surface. In one embodiment, the etch stop layer 222 is a layer of CVD deposited silicon nitride. Alternatively, other materials such as aluminum nitride or aluminum oxide and other deposition methods, such as PVD or combinations of CVD and PVD can be used to form the etch stop layer 222. The ILD layer 224 can be formed using any of the materials or processes previously described to form the ILD layer 218. In accordance with one embodiment, the ILD layer 224 is a layer of CVD silicon dioxide having a thickness in a range of approximately 300-600 nanometers.

Next, the substrate surface is patterned and etched using conventional processes to define trenches 225 and contact window openings 227 within the ILD layer 224, stopping the etch on etch stop layer 222. The etch process then uses a chemistry which etches the etch stop layer 222 so that the contact window openings 227 extend to the conductive plugs 220a and 220b. In an alternate embodiment, if an endpoint etching process or a well controlled timed etch process is used to form the trenches and contact window openings, the use of the etch stop layer 222 may not be necessary.

Next, a relatively thin layer of high-permeability magnetic material 226 is deposited overlying the substrate surface. Typically, the layer of high-permeability material 226 includes an alloy material, such as nickel-iron (NiFe) or nickel-iron-cobalt (NiFeCo). In accordance with one embodiment, the thickness of the layer of high-permeability magnetic material 226 is in a range of approximately 5-40 nanometers. High-permeability magnetic material 226 serves as a magnetic field focusing layer. To improve adhesion of the high-permeability magnetic material 226 or to provide a barrier to prevent species of the high-permeability magnetic material from diffusing into the ILD layer 224, a layer of titanium nitride, tantalum, tantalum nitride, or other such material can be formed between the layer of high-permeability magnetic material 226 and the ILD layer 224.

A conductive layer 228 is then deposited over the layer of high-permeability magnetic material 226 to substantially fill the trenches 225 and contact window openings 227 and form the structure as shown in FIG. 3. In accordance with one embodiment, the conductive layer 228 is a layer of copper, which includes a PVD deposited seed layer (not separately shown) and an electroplated overlayer. Alternatively, the conductive layer 228 can be formed using other materials such as aluminum, aluminum alloys, copper alloys, or combinations thereof. To improve adhesion or to provide a barrier protection, a layer of titanium nitride, tantalum, tantalum nitride, or the like can formed between layer of high-permeability magnetic material 226 and the conductive layer 228.

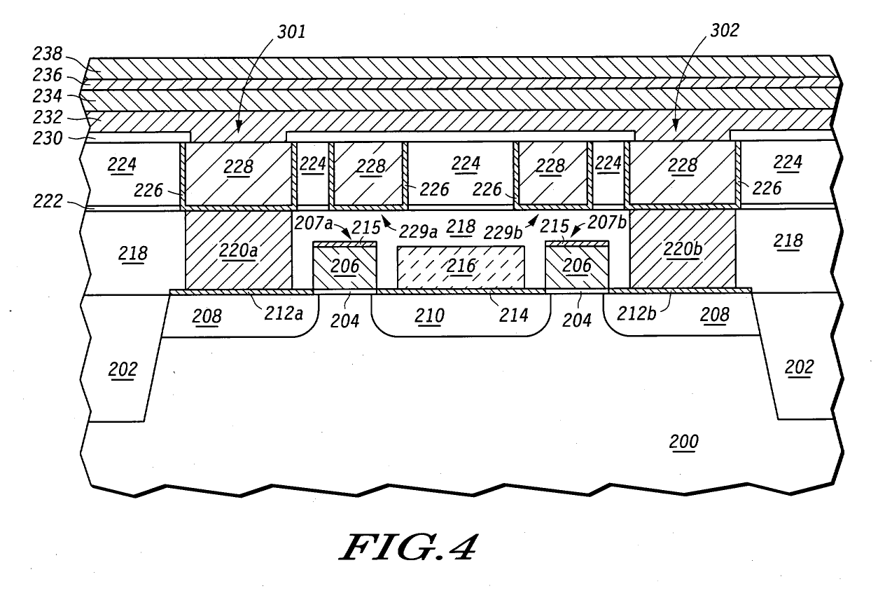

Turning now to FIG. 4, after depositing the conductive layer 228, portions of the conductive layer 228 and high-permeability magnetic material 226 not contained within the trench openings 225 and the contact window openings 227 are removed and the substrate surface is planarized using a conventional CMP process. At this point, digit lines 229a and 229b have substantially been formed. Digit lines 229a and 229b are partially surrounded by remaining portions of high-permeability magnetic material 226. These remaining portions of high-permeability magnetic material 226 help to reduce the digit line's magnetic flux leakage and to focus the digit line's magnetic fields towards overlying magnetic memory elements that will subsequently be formed.

A dielectric layer 230 is then deposited overlying the substrate surface, including over digit lines 229a and 229b. The dielectric layer 230 is patterned and etched to form openings 301 and 302 over conductive plugs 220a and 220b as shown in FIG. 4. Next, a conductive layer 232 is deposited over dielectric layer 230. Dielectric layer 230 electrically isolates the digit lines 229a and 229b from the conductive layer 232. In accordance with one embodiment, the thickness of the conductive layer 232 is in a range of approximately 40-60 nanometers.

Next, magnetic memory element layers 234, 236 and 238 are deposited over the conductive layer 232. The magnetic memory element layers 234, 236 and 238 can be deposited using PVD, ion beam deposition (IBD), CVD, combinations thereof, or the like. The bottom magnetic memory element layer 234 and the top magnetic memory element layer 238 utilize magnetic materials, such as NiFe (including Permalloy), CoFe, NiFeCo, and the like. The middle memory element layer 236 typically comprises a thin tunnel dielectric material such as aluminum oxide (Al₂O₃), in a MTJ array, and copper (Cu) in a GMR array. In one embodiment, memory element layer 236 is formed by first depositing an aluminum film over bottom magnetic memory element layer 234 and then oxidizing the aluminum film using an oxidation source, such as an RF oxygen plasma. Alternatively, aluminum oxide is deposited on magnetic memory element layer 234, followed by a subsequent process in a heated or unheated oxygen ambient to ensure complete oxidation of the aluminum. The thicknesses of magnetic memory element layers 234 and 238 are typically in a range of approximately 2-20 nanometers. The thickness of the memory element layer 236 is typically in a range of approximately 1-3 nanometers. One of the magnetic memory element layers 234 and 238 must form the fixed layer and the other the free layer. In a preferred embodiment, the bottom magnetic memory element layer 234 is the fixed layer and the top magnetic memory element layer 238 is the free layer. Formation of the fixed and free layers can follow materials and structures known in the art. The fixed layer can use a magnetic material with a higher coercive field than that of the free layer material. Alternatively, geometrical effects such as thickness or length-to-width aspect ratios can be used to make the free layer easier to switch than the fixed layer. Multilayer stacks such as a nonmagnetic or antiferromagnetic layers sandwiched between two magnetic layers with opposite magnetization vectors also can be used to form the fixed layer. Multilayer stacks (for example, of CoFe with NiFe) also can be used to form the free layer.

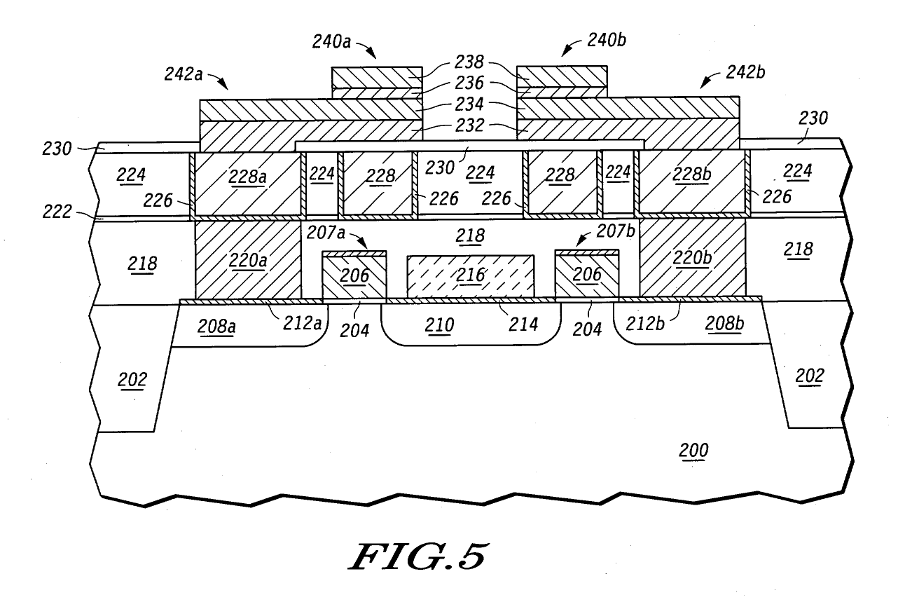

Turning now to FIG. 5, the substrate surface is patterned and etched to form magnetic memory elements 240a and 240b from remaining portions of memory element layers 236 and 238 and to form conductive members 242a and 242b from remaining portions of conductive layer 232 and memory element layer 234. The conductive member 242a interconnects magnetic memory element 240a to transistor 207a via conductive plug 220a and conductive member 228a, and the conductive member 242b interconnects magnetic memory element 240b to transistor 207b via conductive plug 220b and conductive member 228b. To form magnetic memory elements 240a and 240b and conductive members 242a and 242b, two masking and etch steps are used. A first mask and etch is used to pattern memory element layers 236 and 238 and a second mask and etch is used to pattern memory element layer 234 and conductive layer 232 to produce the structures shown. Etch chemistries are selected based upon the differences in materials of the various layers being etched and surrounding layers, e.g. conductors and dielectrics.

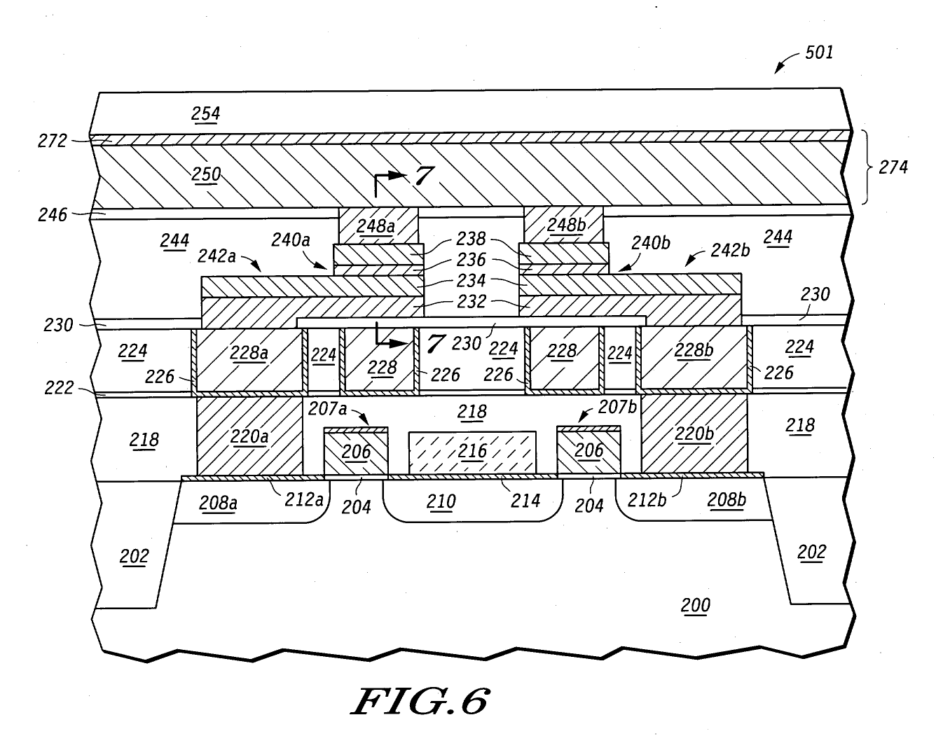

Referring now to FIG. 6, in accordance with one embodiment, after forming the magnetic memory elements 240a and 240b and conductive members 242a and 242b, an ILD layer 244 is deposited over the substrate surface. In the preferred embodiment a CMP process will be used to planarize ILD layer 244. Then etch stop layer 246 is deposited overlying the ILD layer 244. Then portions of the etch stop layer 246 and ILD layer 244 overlying magnetic memory elements 240a and 240b are removed by etching to define openings that expose portions of the magnetic memory elements 240a and 240b. Next, a conductive layer 248 is deposited over the substrate surface and within the openings of the etch stop layer. In a preferred embodiment, conductive layer 248 is copper or a predominantly copper alloy for devices using copper interconnects. For aluminum interconnects, conductive layer 248 may be tungsten. Then the conductive layer 248 is polished to form conductive members 248a and 248b, also referred to as conductive vias, as shown in FIG. 6. One of ordinary skill in the art recognizes that up to this point, the process of fabricating the MRAM device has been conventional. Although processing of the MTJ device has been described, one skilled in the art appreciates that a GMR device using the present invention can be fabricated using known methods up to this point, as well.

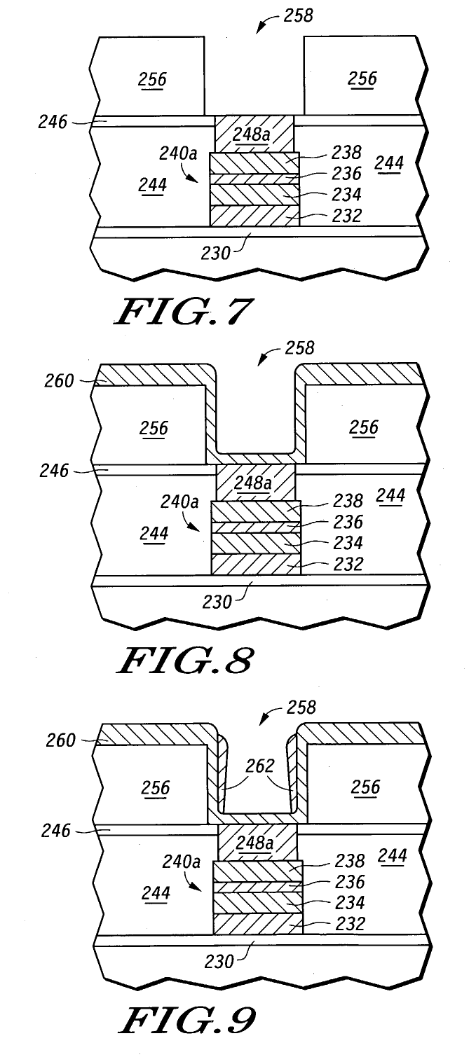

Referring now to remaining portions of FIG. 6 and FIGS. 7-12, an embodiment of the present invention will be discussed in further detail. FIG. 6 shows a cross section of a substantially completed MRAM device 501 that includes a bit line structure 274. The cross-section extends substantially along the same axis as a length of the bit line structure 274 and shows that the bit line structure 274 electrically connects to the magnetic memory elements 240a and 240b. The bit line structure 274 is a magnetically clad bit line structure that includes a bulk conductive material 250, preferably of copper, and a top magnetic cladding capping layer 272, preferably comprising nickel and iron. A sidewall magnetical cladding is also included, but is not visible in this view of the MRAM device (see FIGS. 7-12). As will become apparent below, conductive material 250 may be one of a number of layers and materials used to form the bit line in accordance with the invention. Overlying the bit line structure 274 is a passivation layer 254, preferably a laminated layer consisting of plasma enhanced nitride (PEN) and silicon oxy-nitride (SiON).

FIGS. 7-12 include an enlarged cross-sectional view illustrating a sequence of processing steps used to fabricate an embodiment of the present invention, which includes the magnetic clad bit line 274 for the MRAM device 501 shown in FIG. 6. The views shown in FIGS. 7-12 include a cross-section through the dielectric layer 230, conductive layers 232, magnetic memory element 240a and the conductive member 248a as indicated by the arrows 7-7 of FIG. 6. The cross-sections of FIGS. 7-12 are thus substantially along the same axis as the width of the bit line structure.

Referring now particularly to FIG. 7, after forming the conductive members 248a and 248b (248b not shown in FIG. 7) an ILD layer 256 is formed over the etch stop layer 246 (the ILD layer 256 is not shown in FIG. 6 due to the orientation of the cross-section FIG. 6). In one embodiment, the ILD layer 256 has a thickness of approximately 300-600 nm and is a silicon dioxide based material deposited by CVD and formed using TEOS as a source gas. Alternatively, ILD layer 256 can be a layer of silicon nitride, a layer of PSG, a layer of BPSG, a SOG layer, a layer of SiON, a polyimide layer, a layer of a low-k dielectric material, a combination of the forgoing materials, or the like.

After depositing the ILD layer 256, the substrate surface is patterned and etched to form a trench 258 in the ILD layer 256. As shown in FIG. 7, the trench 258 is substantially aligned with the conductive member 248a and the magnetic memory element 240a. While perfect alignment and size matching is difficult to achieve, etch stop layer 246 provides sufficient process latitude to prevent over etching of trench 258 while ensuring it is sufficiently cleared. Although not shown in FIG. 7, the trench extends in a longitudinal direction, such that it coincides with the bit line to be formed and is substantially aligned with other magnetic memory elements associated with the bit line structure.

Next, a layer of a diffusion barrier 260 is deposited over the ILD layer 256 and within the trench 258 as shown in FIG. 8. In one embodiment, diffusion barrier 260 is a layer of tantalum deposited by conventional physical vapor deposition (PVD) or ionized PVD to a thickness of about 300-400 angstroms or 30-40 nanometers (as measured on the top of ILD layer 256, which results in a thickness on the sidewalls and the bottom of trench of about 40-100 angstroms or 4-10 nanometers for a trench opening having an aspect ratio of 1.8 to 2.5. Diffusion barrier 260 serves to prevent diffusion of the bulk conductive bit line material (preferably copper) from diffusing into the surrounding ILD layer 256 and into underlying transistors and memory elements. Other suitable diffusion barrier materials include tantalum nitride, tantalum silicon nitride, and tungsten. Other deposition techniques, such as atomic layer deposition may also be used.

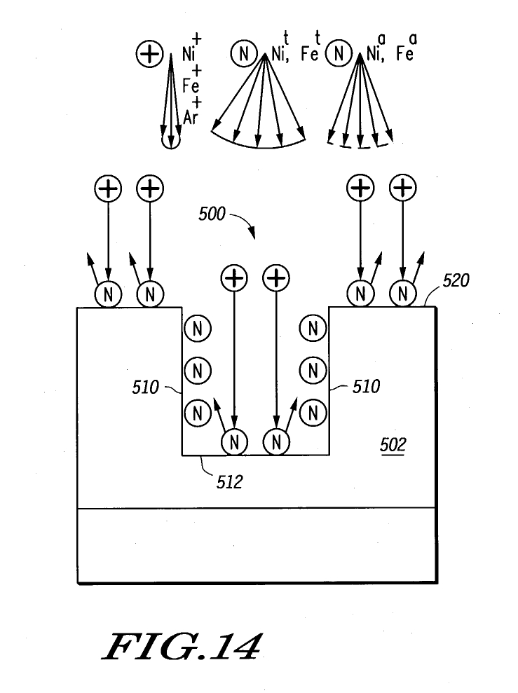

Following deposition of the diffusion barrier 260, a high-permeability magnetic material is selectively deposited onto the sidewalls of trench 258 to form magnetic cladding sidewalls 262 as shown in FIG. 9. In accordance with one embodiment, the high-permeability magnetic material layer includes NiFe, or more specifically Permalloy (Ni_{80.5}Fe_{19.5}). Alternatively, the high-permeability magnetic material can be a layer of NiFeCo or CoFe, but other magnetic materials capable of performing the function needed in an MRAM device may be used instead. As used herein, high-permeability includes, but is not limited to, those having a ratio of magnetic inducticion, B, to the magnetic field greater than 500. The cladding materials also preferably have a low coercivity (Hc) (e.g. <100 Oresteds), which relates to how quickly with respect to the applied filed the magnetic induction will respond. In MRAM applications, it is desirable to have the magnetization easily reversed, thus the desire for low coercivity. A particular process for forming magnetic cladding sidewalls 262 will be described in more detail below in reference to FIGS. 13 and 14. Briefly stated, sidewalls 262 are formed in accordance with the present invention through a re-sputtering operation whereby material which is deposited onto the bottom of the trench opening is resputtered off the bottom of the trench and re-deposited on the sidewalls. Thus, it is a selective cladding deposition process.

Preferably, the thickness of the magnetic cladding sidewalls 262 will be 40-100 angstroms (4-10 nm). Ideally, the thickness is uniform along the sidewalls, but in practice the thickness may vary, as shown in FIG. 9 being thicker near the top of the trench. One of ordinary skill in the art realizes that as technology advances, the trench dimensions may shrink. If the trench shrinks, the thickness of high-permeability magnetic material may not be within the 4-10 nm range. If this is the case, another thickness, which does not fill the trench but which provides sufficient cladding properties, should be chosen. In a preferred embodiment, the re-sputtering process used to form magnetic cladding sidewalls 262 is selective to underlying diffusion barrier 260 at the bottom of the trench. For example, in using a tantalum diffusion barrier 260 and a NiFe cladding material, the sputter thresholds of these two materials are sufficiently different to enable sputtering of the NiFe without likewise removing a tantalum layer.

In accordance with a preferred embodiment of the invention, magnetic cladding sidewalls are formed without exposing diffusion barrier 260 to ambient, thereby preventing oxidation of the diffusion barrier material and thus maintaining sufficiently low via resistance and preventing the need to perform a pre-clean step prior to depositing the bulk conductive bit line material. This may be accomplished by depositing diffusion barrier 260, e.g. tantalum, then transferring the wafer under vacuum to a chamber for depositing the magnetic cladding material. Such transfers can be accomplished using commercially available cluster tools which include multiple processing chambers.

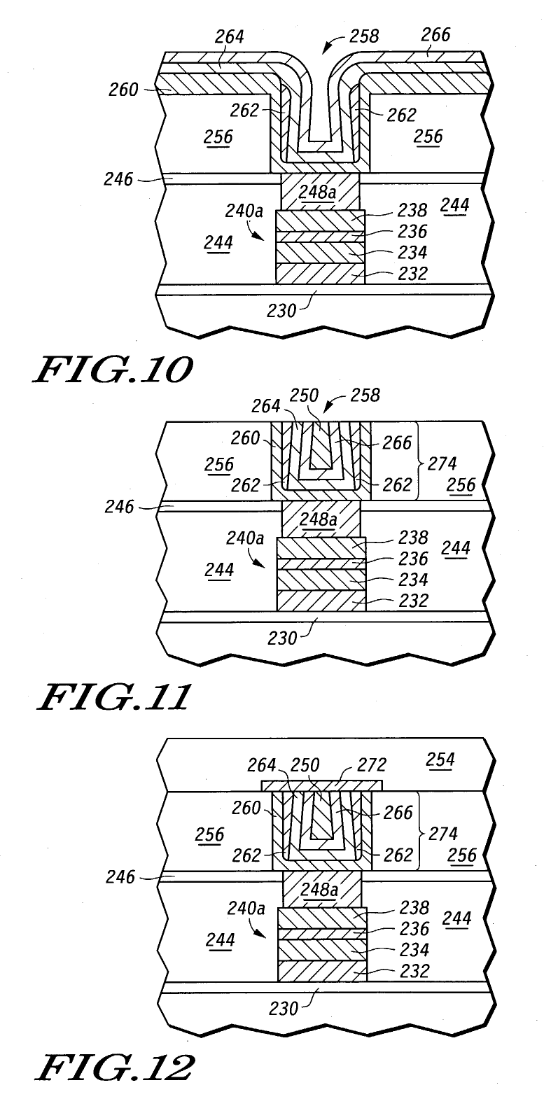

After the magnetic cladding sidewalls are formed, an additional diffusion barrier layer 264 is deposited over the device, including within trench 258, as shown in FIG. 10. The purpose of this diffusion barrier is to again prevent diffusion of the bulk conductive bit line material (preferably copper) from diffusing into surrounding layers, and particularly to prevent unwanted interaction between copper and nickel-iron used to form the sidewall cladding. Suitable materials and thicknesses for diffusion barrier layer 264 are the same as previously discussed with reference to diffusion barrier 260.

In preparation for forming the bulk of the conductive bit line, a conductive seed layer 266 is deposited over the device as also shown in FIG. 10. For example, seed layer 266 may be a copper seed layer deposited using plasma vapor deposition (PVD), or preferably an ionized PVD process deposited to a thickness of about 500 angstroms (50 nm).

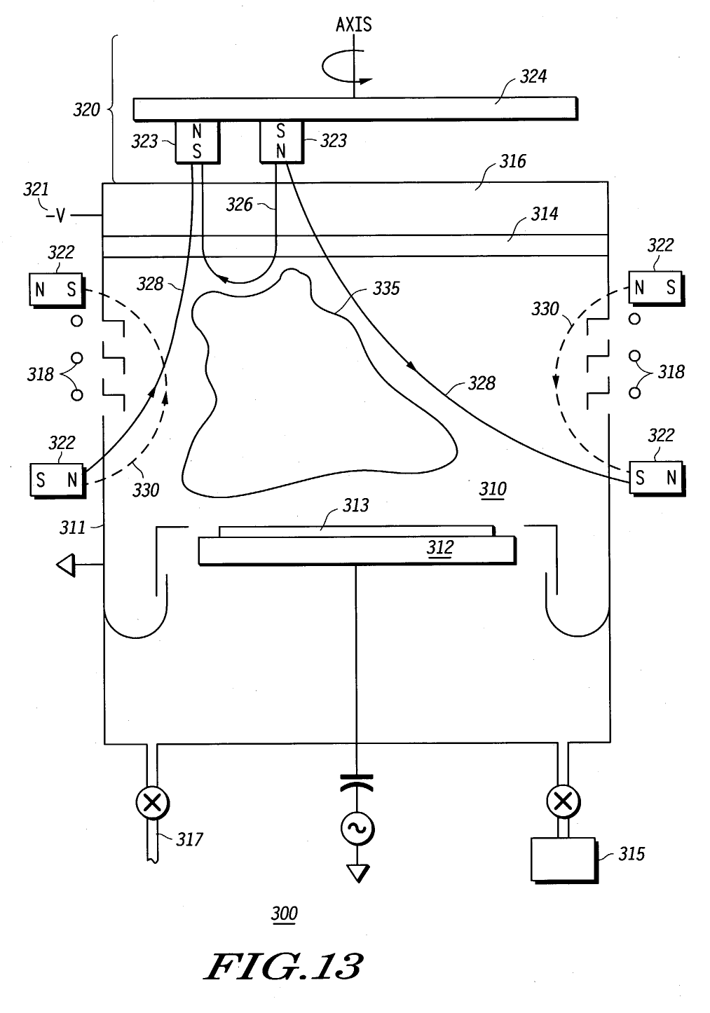

Next, a layer of conductive material 250 is deposited overlying the substrate surface and within the trench 258, thereby filling the trench as shown in FIG. 11. This conductive material is used to form the bulk of the conductive bit line. In accordance with a preferred embodiment, this conductive material is formed of copper. Alternatively, it can include other materials such as copper alloys, aluminum, or aluminum alloys including aluminum-copper. The conductive material or layer used to form conductive bit line structure 274 can be deposited using PVD, CVD, electroplating, electroless plating, or combinations thereof. Preferably the conductive material will be deposited by plating, thus the need for seed layer 266, and will have a thickness that substantially fills the trench. After deposition, this conductive material and the diffusion barriers 264 and 260 overlying the top of ILD layer 256 are planarized, preferably using a chemical mechanical polishing (CMP) process to produce a cladded conductive bit line structure 274 as shown substantially in FIG. 11, albeit not to scale. For a trench having an initial width of approximately 1300 angstroms (130 nm) and an initial depth of 4200-5200 angstroms (500-600 nm), taking into account the thicknesses of the previously described layers along the sidewalls of the trench, the conductive bit line will have a width of approximately 1000 angstroms (100 nm) and a thickness of 4000-5000 angstroms (400-500 nm). One of ordinary skill recognizes that this thickness requirement will vary as a function of the depth and width dimensions of the trench and accordingly will vary as dimensions of the overall device structure shrink. It is noted that the conductive bit line structure 274 shown in FIG. 11 is not drawn to scale given the various thickness ranges for the various layers depicted.

Referring now to FIG. 12, after planarization, a cladding capping layer 272 formed of a high-permeability material such as nickel-iron (NiFe), e.g. Permalloy, is deposited overlying the ILD layer 256 and is patterned and etched so as to form a cap over conductive bit line structure 274. With capping layer 272, the bit line structure is now suitably clad on both the sidewall and top surfaces. Other materials having high permeability properties such as NiFeCo or CoFe can be used to form a magnetic cladding material or a capping layer 272. Typically, the magnetic capping material has a thickness of about 250 angstroms (25 nm). In accordance with one embodiment, the magnetic cladding layer 272 is deposited using a PVD process. Alternatively, the magnetic cladding capping layer 272 can be formed using ion beam deposition (IBD), CVD, electroplating, combinations thereof, or the like. While the capping layer 272 is shown as being formed by deposition and patterning, alternative techniques can instead be used. For example, conductive bit line structure 274 could be partially recessed within trench 258, allowing a capping layer to fill the trench and a CMP process could be used to remove the cap from elsewhere over ILD layer 256. While an upper capping layer such as capping layer 272 is preferred for use in an MRAM device to enhance the magnitude of the magnetic field, such is not a requirement for purposes of practicing the present invention.

FIG. 13 is a cross-sectional representation of a generic chamber 310 in a sputtering tool 300 which may be used for selectively depositing magnetic cladding sidewalls in accordance with the present invention. This chamber representation has been drawn to illustrate different designs which would make possible the described deposition process. Those skilled in the art will appreciate that all features shown are not necessarily required for a sputtering tool used in accordance with the invention. Rather, the various features are intended to demonstrate available features for achieving the desired result.

The general requirements of a chamber configuration and settings are that it provide a deposition precursor flux (e.g. the Ni, Fe neutrals and ions that deposit) that is balanced by or exceeded by a sputter agent ion flux (e.g. argon, nickel, and iron ions) weighted by the ion sputter yield. These conditions will result in deposition of the precursor onto trench sidewalls without deposition on the bottom of the trench. There are two components which can be varied and which relate to one another to achieve this condition. The two components are the plasma generation power source and the wafer bias power source. For the plasma generation power source component, which generates the precursor flux and sputter agent flux, the following configurations could be used: an unbalanced magnetron configuration; inductively coupled coils; electron cyclotron resonance (ECR); microwaves; electron beam induced or surface wave discharges. To provide an adequate sputter yield, a wafer bias power source is needed. The relation between the two components is that the wafer bias power will scale with the total flux of both the deposition precursor and the sputter agent.

Generally, a condition for resputtering sidewall cladding is that the current (RF or any other frequency driven by a power supply beneath the pedestal) be low enough that at reasonable powers (300 W-1000 W) the voltage driven by the power supply at the pedestal is substantially greater than the sputter threshold of NiFe (or whatever magnetic material is being used for the cladding) for the dominant ion species in the plasma. At the same time the plasma should be sufficiently dense to supply adequate depositing species (neutral or ionized) into the feature while providing sufficient ion flux for sputtering. Additionally, the voltage should be such that the product of the sputter threshold and the incident flux of ions exceeds or matches the deposition rate of depositing species (Ni or Fe or another atom). In one embodiment, this combination of effects may be achieved by operating a magnetron in unbalanced mode at low power or by operating a conventional PVD chamber in balanced mode with a supplemental plasma source at low enough coupled power to effect the described conditions.

A discussion of sputtering tool 300 of FIG. 13 may aid in the understanding of how one may fulfill the aforementioned characteristics of a sputtering process. Sputtering tool 300 includes chamber sidewalls 311, a substrate chuck 312 for holding a semiconductor wafer 313, a sputtering target 314, a backing plate 316 to provide structural support for target 314; inductive coils 318 surrounding a perimeter of chamber 310, a magnetic assembly 320 positioned above the sputtering target, magnets 322 located about the chamber 310, a gas source 315 and an exhaust port 317.

Target 314 is comprised of a high-permeability magnet material, for example NiFe, NiFeCo, or CoFe, and is a substantially planar target within the chamber. Planarity of the target is important particularly with magnetic target materials to ensure a uniform erosion of the target, but also to more uniformly distribute a plasma within the chamber, as described below. The target layer thickness of magnetic materials is generally thinner than target materials which are non-magnetic because the magnetic fields from magnetic assembly 320 must penetrate through the target layer (and if too thick could not penetrate). Because the target layer is so thin, a backing plate 316 (e.g. a stainless steel plate) may be used to provide structural support for the target layer. In accordance with the present invention, the target is powered during a selective sidewall cladding deposition operation by applying a negative voltage of between about 300-2000 Volts using a voltage source 321. The voltage is chosen to have a power per unit area of the target of about 0.5 to 2 Watts per unit target area of 1 cm². For a typical target of 1000 square centimeters, this corresponds to a power of 500 Watts to 2000 Watts.

This power range is determined by deposition rate requirements and bias power requirements. Consider first the deposition rate requirements. Permalloy films are thin and require a minimum deposition time for controllable processes. Relating reasonable target powers to deposition rates is found by relating current to the incident flux, sputter rate and relationship between yield and incident ion energy. Power is described by:

P=IV=e(Γᵢₒₙ×A_{T arg et}×V) [1]

where P is the power applied to the target, I, is the current incident on the target, V is the voltage applied to the target, e is an electric charge, Γᵢₒₙ is the ion flux incident on the target and A is the area of the target. The sputter yield, Y, of Ar ions on Permalloy is ˜αV, where V is the target voltage in Volts and α is a proportionality constant approximately equal to 0.002V⁻¹. Using the relationship between flux, sputter rate (SR) and target density ρ,

$$P = e ( \frac{SR \times ρ}{Y} \times {A}_{target} \times V ) \qquad [ 2 ]$$

and applying the linear relation between yield and voltage, the sputter rate becomes,

$$SR \approx ( \frac{α P}{e \times {A}_{target} \times ρ} ) . \qquad [ 3 ]$$

When sputtered from a surface, sputtered species have energies from 1-5 eV. It is often desired to have some fraction thermalize (cool by collisions to near the background gas temperature, on the order of a few hundred degrees Celcius) so that some of the sputtered species may be ionized. These conditions dictate that the sputtered species must experience a few collisions between the target and the wafer. This collisionality dictates the chamber's target-to-wafer distance and tends to result in a fraction of sputtered material being deflected to surfaces other than the wafer or back to the target. The fraction that makes it to the wafer is on the order of 10-75% (for illustration we will use 50% as an example) and thus the deposition rate, DR is equal to the sputter rate of the target divided by 2.

For a target on the order of 1000 cm², and a solid target density on the order of 9×10²² cm−3, the deposition rate, DR, is ˜0.025 angstroms/sec/Watt. A 10 second process required to deposit 250 angstroms would require a power of approximately 1000 Watts if the magnet were designed to cover a large fraction of the surface with cusp magnetron plasmas. Smaller magnet coverage will result is larger required powers. The bias power coupling relationship to the target power will be discussed below.

Returning again to the configuration of sputtering tool 300, the magnetic assembly 320 of the sputtering tool 300 is located above the target and includes magnets 323 attached to a support structure 324. Magnets 323 create a magnetic field partially represented in FIG. 13 as magnetic field line 326. Magnetic assembly 320 rotates about the Y-axis as shown in FIG. 13 to move the magnetic fields (and thus the plasma) within the chamber for more uniform deposition onto the wafer and to provide more uniform erosion of the target.

Magnets 322 are positioned about the chamber, preferably outside the chamber, to provide substantially unbalanced magnetic fields within the chamber. As is apparent from FIG. 13, magnets 322 act together with magnets 323 to create magnetic fields represented by magnetic field lines 328, and magnets 322 act amongst themselves to create magnetic fields represented by magnetic field lines 330. As used herein “unbalanced” field lines generally refer to field lines that leave but do not re-enter the target area, or in other words which are not confined to the portion of the chamber near the target, but instead extend substantially into the chamber. Unbalanced magnetic fields are desirable to confine the plasma in a downward direction toward the semiconductor wafer and to promote ionization of neutral species as they travel to the wafer surface. This is especially important as the target power is lowered. Unbalanced magnets can be used to increase ion density to ensure deposition occurs even at low target powers (e.g. below 5 kWatts).

To this point, plasma sustained by the sputter source in unbalanced mode has been described. Alternatively, a supplemental plasma source may be used to sputter the target or to bring about sputtering at a wafer by supplying the wafer with current in the case that the ion flux or current to the wafer is inadequate without it. An example of a chamber configuration which may have inadequate current at the wafer would be a balanced magnetron configuration. A supplemental plasma 335 may be generated by applying radio frequency (RF) power to inductive coils 318 (a primary of a transformer) which couple magnetically to stray electrons in the chamber. These stray electrons, provided by a source gas such as argon, further collide with neutral atoms within the source gas to produce further electrons which provide a current, thereby forming the secondary of the transformer. Inductive coils 318 distribute the plasma throughout chamber 310, providing a substantial path by which neutrals atoms from target 314 become ionized and are deposited onto wafer 313. In the case of supplemental inductive plasma sources, inductive coils 318 should be isolated from the magnetic material to allow RF magnetic fields to penetrate into the plasma. Other plasma sources may be envisioned such as ECR, microwave, electron beam induced or surface wave discharges. Those skilled in the art will recognize that methods of increasing plasma density in a balanced system other than those specifically mentioned herein may also be employed.

Also in accordance with an embodiment of the present invention, substrate chuck 312 is RF biased as shown in FIG. 13. Biasing increases the potential difference between the semiconductor wafer 313 and the plasma. Positive ions are accelerated through this potential difference to impact the wafer. Suitable biasing conditions for substrate chuck 312 are between 50-200 Volts. Generally speaking, a “high” wafer bias deposition process is used to get deposition on the sidewalls as a result of re-deposition of atoms from the bottom of the trench. High wafer bias conditions can be affected through high RF power applied to the wafer (e.g. 500 to 1000 Watts) or by increasing the impedance at the wafer by decreasing frequency (e.g. less than 10 MHz). Generally, the higher the wafer power, the higher you need the target power to achieve effective resputtering.

FIG. 14 is a depiction of how sputtering tool 300 selectively deposits the target material onto sidewalls of a trench. FIG. 14 includes a simplified illustration of a trench 500 formed in an ILD layer 502. Trench 500 has sidewalls 510 and bottom 512. ILD layer 502 has a top surface 520. In accordance with the present invention, the plasma generated within sputtering tool 300 includes ionized source gas atoms (e.g. ionized argon atoms), neutral target atoms (e.g. neutral Ni and neutral Fe atoms), and ionized target atoms (e.g. ionized Ni and ionized Fe atom). Furthermore, the neutral target atoms will be of two kinds, thermal and athermal. Thermal neutral target atoms are atoms that generally have been directed sufficiently through and within the plasma to have come to the same temperature as the plasma (e.g. 700° C.). Athermal neutral target atoms are atoms which more directly pass through the plasma to the semiconductor wafer in a more direct path and without coming to the plasma temperature.

As shown in FIG. 14, ionized atoms (e.g. Fe⁺, Ni⁺ and Ar⁺) are highly directional, traveling virtually straight from the target to the semiconductor wafer. Thermal neutral atoms (e.g. Fe^{t}, and Ni^{t}) are less directional (i.e. the angle of incidence upon contacting ILD layer 502 is more distributed) than the ionized atom, but the athermal neutral atoms (e.g. Fe^{a}, and Ni^{a}) are more directional than the thermal neutral atoms (e.g. Fe^{t}, and Ni^{t}). Neutral atoms are generally the atoms which deposit on the ILD surface, whereas the ionized atoms more generally act as a sputtering agent. Accordingly, the directional ionized atoms will help remove deposited neutral atoms from the top surface 520 and bottom 512 of ILD layer 502, as shown in FIG. 14. Within trench 500, the neutral atoms sputtered from bottom 512 of the trench will be redeposited on sidewalls 510 of the trench. This deposition and re-sputtering action occurs throughout the deposition process so that the end result is to have a build-up of material on the sidewalls with negligible net deposition on the top surface 520 of ILD layer 502 and bottom 512 of trench 500. This result is depicted in reference to FIG. 9, showing magnetic cladding sidewalls 262 on only sidewalls of trench 258.

As is apparent from the foregoing description, the present invention provides a method for forming magnetic cladding sidewalls in a bit line structure for a magnetic memory cell without many of the problems associated with prior art processes. For example, by using a re-sputtering process, whereby magnetic material is deposited on a trench bottom and is then re-sputtered to deposit on the sidewalls of the trench, there is no need to perform a separate etch step to remove the magnetic material from the bottom of the trench. This not only eliminates an etch step, but also subsequent chamber cleaning steps which have historically been needed to clean the magnetic material from the dome of an etch chamber. These cleaning steps can be anywhere from one to fifteen times longer than the actually etch of the magnetic material itself. Yet another advantage is that a tantalum layer used as a diffusion barrier need not be exposed to air prior to formation of the magnetic cladding sidewalls. By using a cluster tool, after depositing tantalum diffusion barrier 260, the wafer is transferred under vacuum to another chamber to deposit the NiFe or other magnetic material along sidewalls in accordance with the invention. Thus, the layer will not oxidize and via resistance can be kept low.

In the foregoing specification, the invention has been described with reference to specific embodiments. However, one of ordinary skill in the art appreciates that various modifications and changes can be made without departing from the scope of the present invention as set forth in the claims below. For example, the invention is not limited to cladding in a trench but rather can be used within any depressed or recessed feature. Furthermore, the invention could be used to clad any sidewall, not just that of a bit line. Accordingly, the specification and figures are to be regarded in an illustrative rather than restrictive sense, and all such modifications are intended to be included within the scope of the present invention. Benefits, other advantages, and solutions to problems have been described with regard to specific embodiments. However, the benefits, advantages, solutions to problems, and any element(s) that may cause any benefit, advantage, or solution to occur or become more pronounced are not to be construed as a critical, required, or essential feature or element of any of the claims.

What is claimed is:

1. A method for forming a semiconductor device comprising:
forming magnetic memory elements overlying a semiconductor device substrate;
forming a dielectric layer overlying the magnetic memory elements;
forming a trench opening within the dielectric layer, wherein the trench opening has sidewalls and a bottom;
forming magnetic cladding sidewalls adjacent the sidewalls of the trench opening, wherein forming magnetic cladding sidewalls comprises:
providing a sputtering tool;
placing the semiconductor device substrate within the sputtering tool;
sputtering a magnetic material from a source target;
biasing the semiconductor device substrate; and
selectively depositing the magnetic material adjacent the sidewalls of the trench opening to form the magnetic cladding sidewalls;
forming a conductive material within the trench opening; and
forming a magnetic cladding cap overlying the conductive material.

2. The method of claim 1 wherein selectively depositing the magnetic material adjacent the sidewalls of the trench opening comprises:
depositing a magnetic material within the trench opening; and
resputtering the magnetic material from the bottom of the trench opening to the sidewalls of the trench opening.

3. The method of claim 1 wherein:
sputtering the magnetic material further comprises:
introducing a plurality of atoms of a first species into the sputtering tool;
physically impacting the source target with the plurality of the atoms of the first species to remove a plurality of atoms of a second species; and
ionizing a portion of the plurality of the atoms of the second species to form ionized second species and nonionized second species; and
selectively depositing the magnetic material adjacent the sidewalls of the trench opening comprises:
depositing the nonionized second species within the trench opening adjacent the sidewalls and the bottom;
substantially removing the nonionized second species from adjacent the bottom of the trench opening by physically impacting the nonionized second species with the ionized second species; and
depositing the nonionized second species removed from adjacent the bottom of the trench adjacent the sidewalls of the trench opening.

4. The method of claim 1, further comprising forming a conductive barrier material between the magnetic cladding sidewalls and the dielectric layer.

5. The method of claim 4, wherein a substantial portion of the conductive barrier material remains over the bottom of the trench opening after forming the magnetic cladding sidewalls.

6. The method of claim 5, wherein the conductive barrier material comprises tantalum.

7. The method of claim 1, wherein the magnetic cladding sidewalls comprise a material selected from the group consisting of NiFe, NiFeCo, and CoFe.

8. The method of claim 1, further comprising forming a conductive barrier material that at least partially surrounds the conductive material and is interposed between the conductive material and the magnetic cladding sidewalls.

9. The method of claim 1, further comprising forming a conductive barrier material adjacent the sidewalls and the bottom of the trench prior to forming magnetic cladding sidewalls, and wherein the magnetic cladding sidewalls are formed without exposing the conductive barrier material to ambient to prevent oxidation of the conductive barrier material.

10. The method of claim 9 wherein the magnetic cladding sidewalls and the conductive barrier material are formed using a same cluster tool.

11. The method of claim 9, wherein the conductive barrier material comprises tantalum.

12. The method of claim 1, wherein the magnetic cladding sidewalls are approximately 40 to 100 Angstroms in thickness.

13. The method of claim 1, wherein a target power per unit area applied to the source target of the sputtering tool is between approximately 0.5-2.0 Watts per square centimeter.

14. The method of claim 1, wherein the sputtering tool comprises a plurality of magnets which are used to generate unbalanced magnetic fields within a chamber of the sputtering tool during sputtering.

15. A method for forming a semiconductor device comprising:
forming a dielectric layer over a semiconductor device substrate;
forming a trench opening within the dielectric layer, wherein the trench opening has sidewalls and a bottom;
providing a sputtering tool having a substantially planar target and unbalanced magnets;
placing the semiconductor device substrate within the sputtering tool;
providing a target power per unit area to the sputtering tool between approximately 0.5-2 Watts per square centimeter;
sputtering a magnetic material from the substantially planar target;
selectively depositing the magnetic material adjacent the sidewalls of the trench opening to form magnetic cladding sidewalls; and
forming a conductive material within the trench opening adjacent the magnetic material adjacent the sidewalls.

16. The method of claim 15, wherein selectively depositing the magnetic material adjacent the sidewalls of the trench opening comprises:
depositing a magnetic material within the trench opening; and
resputtering the magnetic material from the bottom of the trench opening to the sidewalls of the trench opening.

17. The method of claim 16, wherein the magnetic material adjacent the sidewalls are approximately 40 to 100 Angstroms in thickness.

18. The method of claim 15, further comprising forming a conductive barrier material between the magnetic material adjacent the sidewalls and the dielectric layer.

19. The method of claim 18, wherein a substantial portion of the conductive barrier material remains over the bottom of the trench opening after forming the magnetic material adjacent the sidewalls.

20. The method of claim 19, wherein the conductive barrier material comprises tantalum.

21. The method of claim 15, wherein the magnetic material adjacent the sidewalls comprises a material selected from the group consisting of NiFe, NiFeCo, and CoFe.

22. The method of claim 15 further comprising forming a conductive barrier material adjacent the sidewalls and the bottom of the trench, wherein sputtering of the magnetic material occurs after forming the conductive barrier material and without exposing the conductive barrier material to ambient.

23. The method of claim 22 wherein the magnetic cladding sidewalls and the conductive barrier material are formed using a same cluster tool.

24. The method of claim 22 wherein the conductive barrier material comprises tantalum.

25. A method for forming a semiconductor device comprising:
forming magnetic memory elements overlying a semiconductor device substrate;
forming a dielectric layer overlying the magnetic memory elements;
forming a trench opening within the dielectric layer, wherein the trench opening has sidewalls and a bottom;
forming a barrier layer within the trench opening;
sputtering a magnetic material from a target within a sputtering tool;
selectively depositing the magnetic material adjacent the sidewalls of the trench opening, with insignificant deposition along the bottom of the trench opening, to form magnetic cladding sidewalls, wherein during selectively depositing the magnetic material the barrier layer substantially remains; and
forming a conductive material within the trench opening adjacent the magnetic cladding sidewalls.

26. The method of claim 25 wherein the barrier layer is not oxidized before forming the magnetic cladding sidewalls.

27. The method of claim 26 wherein the barrier layer comprises tantalum.

28. The method of claim 25 wherein the semiconductor device substrate is biased during selective deposition of the magnetic material.

29. The method of claim 23 wherein the magnetic cladding sidewalls and the barrier layer are formed using a same cluster tool.
